(19) United States
(12) Patent Application Publication
(10) Pub. No.: US 2026/0006946 A1
(43) Pub. Date: Jan. 1, 2026

(54) SEMICONDUCTOR LIGHT-EMITTING ELEMENT AND METHOD OF PRODUCING SEMICONDUCTOR LIGHT-EMITTING ELEMENT

(71) Applicant: DOWA Electronics Materials Co., Ltd., Chiyoda-ku, Tokyo (JP)

(72) Inventors: Yuta KOSHIKA, Akita-shi, Akita (JP); Yoshitaka KADOWAKI, Akita-shi, Akita (JP)

(73) Assignee: DOWA Electronics Materials Co., Ltd., Chiyoda-ku, Tokyo (JP)

(21) Appl. No.: 18/997,228

(22) PCT Filed: Jul. 19, 2023
(86) PCT No.: PCT/JP2023/026476

§ 371 Date: Jan. 21, 2025

(30) Foreign Application Priority Data
Jul. 22, 2022 (JP) 2022-117526
Jul. 18, 2023 (JP) 2023-116899

(51) Int. Cl. H10H 20/812; H10H 20/824

(52) U.S. Cl. CPC H10H 20/812; H10H 20/824

(57) ABSTRACT

Provided is a semiconductor light-emitting element having good light emission characteristics compared to conventional light-emitting elements. The semiconductor light-emitting element includes a light-emitting layer including a laminate in which first and second III-V compound semiconductor layers are stacked repeatedly. Group III element in the first and second III-V compound semiconductor layers is one type or two or more types selected from the group consisting of Al, Ga, and In. Group V element in the first and second III-V compound semiconductor layers is one type or two or more types selected from the group consisting of As, Sb, and P. A composition wavelength difference between composition wavelengths of the first and second III-V compound semiconductor layers is 70 nm or more. In a band structure of the laminate, conduction band-side well depth (Dc) is larger than valence band-side well depth (Dv), and Dc/(Dc+Dv) is 65% or more.

### TECHNICAL FIELD

The present disclosure relates to a semiconductor light-emitting element and a method of producing a semiconductor light-emitting element.

### BACKGROUND

III-V compound semiconductors such as InGaAsP, InGaAlAs, and InAsSbP are used as semiconductor materials of semiconductor layers in semiconductor light-emitting elements. Through composition ratio adjustment of a light-emitting layer formed using a III-V compound semiconductor material, it is possible to adjust the light emission wavelength of a semiconductor light-emitting element over a wide range from green to infrared. For example, semiconductor light-emitting elements that are infrared-emitting with a light emission wavelength in an infrared region of wavelengths of 750 nm or more are widely used in applications such as sensors, gas analysis, surveillance cameras, and communications.

Patent Literature (PTL) 1 discloses a semiconductor light-emitting element including a light-emitting layer having a layered structure in which a first III-V compound semiconductor layer and a second III-V compound semiconductor layer having different composition ratios are stacked repeatedly, wherein a composition wavelength difference between a composition wavelength of the first III-V compound semiconductor layer and a composition wavelength of the second III-V compound semiconductor layer is 50 nm or less, and a ratio of a lattice constant difference between a lattice constant of the first III-V compound semiconductor layer and a lattice constant of the second III-V compound semiconductor layer is not less than 0.05% and not more than 0.60%.

### CITATION LIST

### Patent Literature

PTL 1: JP2020-109817A

### SUMMARY

### Technical Problem

In recent years, there has been demand for further improvement of light emission efficiency of light-emitting elements. The inventors conducted research with the aim of further improving light emission efficiency over the structure in PTL 1.

Moreover, in applications such as sensors of wearable devices, etc. used at wavelengths of 1,300 nm to 2,200 nm and in gas analysis of carbon dioxide, etc. used at wavelengths of 2,600 nm to 4,700 nm, it is preferable that the full width at half maximum of a light emission peak in a light emission spectrum is narrow in order to use a specific wavelength. There is demand for semiconductor light-emitting elements to have good light emission characteristics in terms of both high light emission output and full width at half maximum (FWHM) of a light emission peak. Accordingly, an object of the present disclosure is to obtain a semiconductor light-emitting element having good light emission characteristics compared to conventional light-emitting elements.

### Solution to Problem

As a result of extensive research conducted diligently with the aim of achieving the object described above, the inventors completed the present disclosure as set forth below.

Specifically, primary features of the present disclosure are as follows.
(1) A semiconductor light-emitting element comprising a light-emitting layer including a laminate in which a first III-V compound semiconductor layer and a second III-V compound semiconductor layer are stacked repeatedly, wherein
group III element in the first III-V compound semiconductor layer and the second III-V compound semiconductor layer is one type or two or more types selected from the group consisting of Al, Ga, and In,
group V element in the first III-V compound semiconductor layer and the second III-V compound semiconductor layer is one type or two or more types selected from the group consisting of As, Sb, and P,
a composition wavelength difference between a composition wavelength of the first III-V compound semiconductor layer and a composition wavelength of the second III-V compound semiconductor layer is 70 nm or more, and
in a band structure of the laminate, well depth (Dc) at a conduction band-side is larger than well depth (Dv) at a valence band-side, and a ratio Dc/(Dc+Dv) of the well depth (Dc) at the conduction band-side created due to the composition wavelength difference relative to a total of the well depth (Dc) at the conduction band-side and the well depth (Dv) at the valence band-side is 65% or more.
(2) The semiconductor light-emitting element according to the foregoing (1), wherein a value obtained when an absolute value of a lattice constant difference between a lattice constant of the first III-V compound semiconductor layer and a lattice constant of the second III-V compound semiconductor layer is divided by an average value of the lattice constant of the first III-V compound semiconductor layer and the lattice constant of the second III-V compound semiconductor layer is not less than 0.10% and not more than 0.40%.
(3) The semiconductor light-emitting element according to the foregoing (1) or (2), wherein the well depth (Dv) at the valence band-side is 0.11 eV or less.
(4) The semiconductor light-emitting element according to any one of the foregoing (1) to (3), wherein the group V element in the first III-V compound semiconductor layer and the second III-V compound semiconductor layer is one type selected from the group consisting of As, Sb, and P.
(5) The semiconductor light-emitting element according to any one of the foregoing (1) to (4), wherein the composition wavelength difference between the composition wavelength of the first III-V compound semiconductor layer and the composition wavelength of the second III-V compound semiconductor layer is not less than 100 nm and not more than 290 nm.
(6) A method of producing the semiconductor light-emitting element according to any one of the foregoing (1) to (5), comprising a light-emitting layer formation step of forming the light-emitting layer, wherein
the light-emitting layer formation step includes forming the laminate through repetition of a first step of forming the first III-V compound semiconductor layer and a second step of forming the second III-V compound semiconductor layer.

### Advantageous Effect

According to the present disclosure, it is possible to provide a semiconductor light-emitting element having good light emission characteristics compared to conventional light-emitting elements and a method of producing the same.

### BRIEF DESCRIPTION OF THE DRAWINGS

In the accompanying drawings:

FIG. 1 illustrates one example of a band structure of a light-emitting layer in a present embodiment as calculated using simulation software;

FIG. 2 is a schematic cross-sectional view illustrating one form of a light-emitting layer in a semiconductor light-emitting element according to the present disclosure;

FIG. 3 is a schematic cross-sectional view illustrating a semiconductor light-emitting element according to one embodiment of the present disclosure; and

FIG. 4 is a schematic cross-sectional view illustrating a method of producing a semiconductor light-emitting element according to one embodiment of the present disclosure using a bonding method.

### DETAILED DESCRIPTION

The following describes various definitions in the present specification in advance of describing embodiments according to the present disclosure.

### <III-V Compound Semiconductor Layers>

Firstly, when referring simply to a “III-V compound semiconductor” in the present specification, the composition thereof is represented by a general formula: (InaGabAlc)(PxAs_{y}Sb_{z}). The following relationships hold for the composition ratios of the various elements.

For the group III elements, c=1−a−b, 0≤a≤1, 0≤b≤1, and 0≤c≤1.

For the group V elements, z=1−x−y, 0≤x≤1, 0≤y≤1, and 0≤z≤1.

A III-V compound semiconductor layer in a light-emitting layer according to the present disclosure contains one type or two or more types of group III elements selected from the group consisting of Al, Ga, and In and one type or two or more types of group V elements selected from the group consisting of As, Sb, and P.

Moreover, in a case in which a III-V compound semiconductor layer in the light-emitting layer contains one type or two or more types of group III elements selected from the group consisting of Al, Ga, and In and one type of group V element selected from the group consisting of As, Sb, and P, the composition ratios of elements in the composition of the III-V compound semiconductor layer have the following relationships.

For the group III elements, c=1−a−b, 0≤a≤1, 0≤b≤1, and 0≤c≤1.

For the group V elements, any one of x, y, and z is 1, and the other two of x, y, and z are 0.

Furthermore, when a III-V compound semiconductor layer in the light-emitting layer contains one type of group V element, it is preferable that the III-V compound semiconductor layer contains two or more types of group III elements, and more preferable that the III-V compound semiconductor layer contains three types of group III elements. Group V element in a III-V compound semiconductor layer in the light-emitting layer preferably includes at least As or Sb. When three or fewer types of elements, in total, are adopted as group III and group V elements, this limits selection choice of a combination of a first layer and a second layer that give composition ratios within the scope of the present disclosure when attempting to obtain a desired light emission wavelength. For this reason, it is preferable that four or more types of elements, in total, are adopted as group III and group V elements in at least one of the first layer and the second layer, and more preferable that four or more types of elements, in total, are adopted as group III and group V elements in both the first layer and the second layer.

### <Lattice Constant Based on Composition>

The following describes calculation of lattice constants of mixed crystals in the present specification. Although there are two types of lattice constants in a vertical direction (growth direction) and a horizontal direction (in-plane direction) relative to the plane of a substrate, a value for the vertical direction is used in the present specification. First, a simple lattice constant for the mixed crystal is calculated in accordance with Vegard's law. Using an InGaAsP system (i.e., a general formula: (InₐGa_{b})(PₓAs_{y})) as an example for illustrative purposes, a physical property constant A_{abxy} (lattice constant according to Vegard's law) is calculated from the following equation <1> based on physical property constants Bₐₓ, B_{bx}, B_{ay}, and B_{by} (literature value lattice constants shown below in Table 1) for the four binary mixed crystals that are the basis for the quasi-quaternary mixed crystal in a case in which each composition ratio (solid phase ratio) is known.

$${A}_{abxy} = a \times x \times {B}_{ax} + b \times x \times {B}_{bx} + a \times y \times {B}_{ay} + b \times y \times {B}_{by} \qquad < 1 >$$

TABLE 1

| | Lattice | | |
|---|---|---|---|
| | constant [nm] | C₁₁ | C₁₂ |
| InP | 0.58688 | 10.22 | 5.76 |
| GaP | 0.54512 | 14.12 | 6.253 |
| InAs | 0.60584 | 8.329 | 4.526 |
| GaAs | 0.56533 | 11.88 | 5.38 |

Next, with regards to elastic constants C₁₁ and C₁₂, elastic constants C_{11abxy} and C_{12abxy} for (InₐGa_{b})(PₓAs_{y}) are also calculated in the same way as in equation <1>.

When the lattice constant of a growth substrate is taken to be as, a (vertical direction) lattice constant a_{abxy} that takes into account lattice distortion can be determined using the following equation <2> by taking into account lattice distortion based on the elastic properties of the semiconductor crystal.

$${a}_{abxy} = {A}_{abxy} - 2 \times ( {a}_{s} - {A}_{abxy} ) \times {C}_{12 abxy} / {C}_{11 abxy} \qquad < 2 >$$

Since InP is used as a growth substrate in a present embodiment, the lattice constant of InP should be used as the lattice constant as of the growth substrate.

In the case of a quasi-ternary mixed crystal, when a general formula: (InₐGa_{b}Al_{c})(As) is taken as an example, the band gap Eg_{abcy} and the lattice constant A_{abcy} according to Vegard's law can be calculated from the following equations <3> and <4>.

$$[ Math . 1 ]$$

$${Eg}_{abcy} = \frac{\{ a \times b \times {E}_{aby} + b \times c \times {E}_{bcy} + c \times a \times {E}_{acy} \}}{( a \times b + b \times c + c \times a )} \qquad < 3 >$$

$${A}_{abcy} = a \times {B}_{ay} + b \times {B}_{by} + c \times {B}_{cy} \qquad < 4 >$$

Note that in a case in which the III-V compound semiconductor is a ternary, pentanary, or hexanary III-V compound semiconductor, the composition wavelength and the lattice constant can be determined by modifying the equations according to the same reasoning as described above. Moreover, in the case of a binary III-V compound semiconductor, the aforementioned literature values can be used.

### <Conduction Band-Side Well Depth (Dc), Valence Band-Side Well Depth (Dv), and Composition Wavelength Based on Composition>

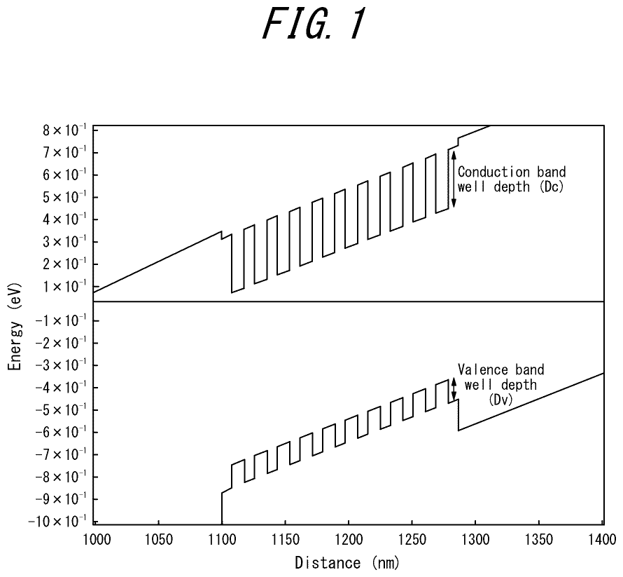

Simulation software (SiLENSe_Version 6.4) produced by STR Japan K.K. was used to calculate a band structure by inputting values for composition ratios of layers in an initial setting state. FIG. 1 illustrates an example of the band structure of a light-emitting layer in a present embodiment as calculated using this simulation software. The horizontal line near the middle of the drawing is the Fermi level. In addition to the band structure being displayed when using this simulation software, an energy band gap Eg (eV) of each layer, a well depth (Dc; units: eV) that is the band gap difference between a barrier layer and a well layer at the conduction band-side, and a well depth (Dv; units: eV) that is the band gap difference between the barrier layer and the well layer at the valence band-side are also calculated. Moreover, the composition wavelength of each layer represented by a wavelength k calculated from the energy band gap Eg by the following equation <5>:

$$Eg = 123 9.8 / λ \qquad < 5 >$$

was also calculated.

### <Film Thicknesses and Compositions of Layers>

The overall thickness of formed layers can be measured using an optical interference film thickness meter. Moreover, the thickness of each layer can be calculated using an optical interference film thickness meter and cross-section observation of a grown layer through a transmission electron microscope. Furthermore, in a case in which layers have small thicknesses of the order of several nanometers like in a superlattice structure, the thickness can be measured using TEM-EDS, and the composition ratios (solid phase ratios) of layers in the present specification are taken to be values obtained through SIMS analysis. The composition ratios (solid phase ratios) of layers of a light-emitting layer in the present specification are taken to be values obtained by implementing SIMS analysis (quadrupole type) in a thickness direction of the light-emitting layer after exposing the vicinity of an uppermost layer of the light-emitting layer through etching. Note that for SIMS analysis results, a value of the average element concentration in a half-thickness range at a central part of each layer in the thickness direction is adopted. In production, a layer having target composition ratios can be stacked by using growth conditions that are determined such as to give the target composition ratios by calculating solid phase ratios using a lattice constant according to XRD measurement and a value determined through conversion of a central emission wavelength according to PL measurement to Eg for a layer grown as a single film.

<p-, n-, i-Types and Dopant Concentrations>

In the present specification, a layer that functions electrically as a p-type is referred to as a p-type layer and a layer that functions electrically as an n-type is referred to as an n-type layer. On the other hand, a layer to which a specific impurity such as Si, Zn, S, Sn, or Mg is not intentionally added and that does not function electrically as a p-type or an n-type is referred to as an “i-type” or as “undoped”. A III-V compound semiconductor layer that is undoped may contain impurities that are unavoidably mixed in during a production process. Specifically, when a layer has a low dopant concentration (for example, less than 7.6×10¹⁵ atoms/cm³), the layer is treated as “undoped” in the present specification. Values for the impurity concentrations of Si, Zn, S, Sn, Mg, and the like are taken to be values according to SIMS analysis. Likewise, values for impurity concentrations (“dopant concentrations”) of n-type dopants (for example, Si, S, Te, Sn, Ge, O, etc.) in active layers are also taken to be values according to SIMS analysis. Also note that values for dopant concentrations are each taken to be the value for dopant concentration at the thickness direction center of that layer because values for dopant concentrations change significantly in proximity to the boundaries of semiconductor layers.

The following provides a detailed, illustrative description of embodiments of the present disclosure with reference to the drawings. Note that constituent elements that are the same are, as a rule, allotted the same reference numbers, and repeated description thereof is omitted. Also note that in the drawings, ratios of the height and width of a substrate and each layer are illustrated in a manner that is exaggerated relative to the actual ratios thereof in order to facilitate description.

### (Semiconductor Light-Emitting Element)

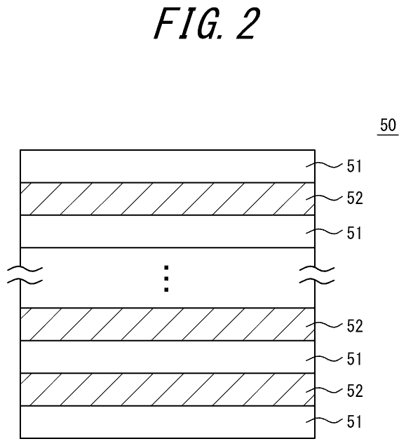

The following refers to FIG. 2, which illustrates one form according to the present disclosure. A semiconductor light-emitting element according to the present disclosure includes a light-emitting layer 50 including a laminate in which a first III-V compound semiconductor layer 51 and a second III-V compound semiconductor layer 52 are stacked repeatedly. The first III-V compound semiconductor layer 51 and the second III-V compound semiconductor layer 52 have different composition ratios to each other. Hereinafter, the first III-V compound semiconductor layer 51 and the second III-V compound semiconductor layer 52 are also referred to simply as a first layer 51 and a second layer 52, respectively. In the semiconductor light-emitting element according to the present disclosure, group III element in the first layer 51 and the second layer 52 is one type or two or more types selected from the group consisting of Al, Ga, and In, and group V element in the first layer 51 and the second layer 52 is one type or two or more types selected from the group consisting of As, Sb, and P. The following describes, as an example, a case in which the first layer 51 is a barrier layer and the second layer 52 is a well layer.

The inventors discovered experimentally that by setting a composition wavelength difference between a composition wavelength of the first layer 51 and a composition wavelength of the second layer 52 as 70 nm or more, setting well depth (Dc) at a conduction band-side created due to this composition wavelength difference as larger than well depth (Dv) at a valence band-side, and setting a ratio Dc/(Dc+Dv) of the well depth (Dc) at the conduction band-side relative to the total of the well depth (Dc) at the conduction band-side and the well depth (Dv) at the valence bands-side as a percentage of 65% or more, it is possible to improve light emission characteristics of the semiconductor light-emitting element over conventional semiconductor light-emitting elements and also to achieve either or both of increased light emission output and narrowing of full width at half maximum in a light emission spectrum.

Although it is not certain why light emission output can be increased and full width at half maximum can be reduced through the composition wavelength difference satisfying the condition set forth above and through the well depth (Dc) at the conduction band-side being larger than the well depth (Dv) at the valence band-side so as to satisfy the condition set forth above, the inventors consider the reason for this to be as follows. In the case of PTL 1, it is thought that a structure that is almost the same as a double heterostructure is adopted as a band structure while also causing valence band splitting due to strain caused by the lattice constant difference and obtaining an electron trapping effect similar to a quantum well structure. In the present disclosure, a small well depth (Dv) is set in the band structure at the valence band and the barrier height is lowered while causing valence band splitting due to strain caused by the lattice constant difference, whereas a large well depth (Dc) is set at the conduction band-side. Trapping electrons/holes by different formats at the valence band and the conduction band in this manner is thought to enable improvement of efficiency of the quantum well structure.

The composition wavelength difference between the composition wavelength of the first III-V compound semiconductor layer and the composition wavelength of the second III-V compound semiconductor layer is 70 nm or more as previously described. This composition wavelength difference is preferably 600 nm or less. Moreover, the composition wavelength difference is more preferably not less than 100 nm and not more than 290 nm in order to improve light emission efficiency.

The ratio Dc/(Dc+Dv) of the well depth (Dc) at the conduction band-side created due to the composition wavelength difference relative to the total of the well depth (Dc) at the conduction band-side and the well depth (Dv) at the valence band-side is a percentage of 65% or more as previously described. The well depth (Dv) at the valence band-side is preferably 0.11 eV or less, more preferably 0.08 eV or less, and even more preferably not less than 0.00 eV and not more than 0.05 eV. Note that the well depth (Dv) at the valence band-side may be zero. The well depth (Dc) at the conduction band-side is larger than the well depth (Dv) at the valence band-side, and is preferably 0.02 eV or more, and more preferably 0.04 eV or more. Although no specific limitations are placed on the upper limit for the well depth (Dc) at the conduction band-side, the upper limit can be set as a value equivalent to half of the band gap between a conduction band and a valence band of the barrier layer. Note that since the ratio relative to the total of the well depth (Dc) at the conduction band-side and the well depth (Dv) at the valence band-side is 100% in a case in which the well depth (Dv) at the valence band-side is zero, the upper limit for the ratio Dc/(Dc+Dv) is, in principle, 100%. The upper limit for the ratio Dc/(Dc+Dv) is preferably 80% or less. The ratio Dc/(Dc+Dv) is more preferably 67% to 70%.

A value obtained when an absolute value of the lattice constant difference between the lattice constant of the first layer 51 and the lattice constant of the second layer 52 is divided by an average value of these two lattice constants (hereinafter, also referred to as the “ratio of lattice constant difference”) is preferably a percentage of not less than 0.10% and not more than 0.40%. This value is more preferably not less than 0.10% and not more than 0.38%. This value is even more preferably 0.20% or more in order to improve light emission output.

Group V element in the first layer 51 and the second layer 52 is preferably one type selected from the group consisting of As, Sb, and P, and is more preferably As or Sb. By limiting the group V element to one type, it is possible to eliminate a phenomenon of group V element diffusion at boundaries between well layers and barrier layers. The elimination of a group V diffusion region enables sharper boundaries between well layers and barrier layers, and thus can enhance effects according to the present disclosure.

Various alterations can be made to the extent that the effects according to the present disclosure are displayed. For example, instead of a case in which the laminate formed of the first layer 51 and the second layer 52 encompasses the entire quantum well structure as in the present embodiment, the laminate formed of the first layer 51 and the second layer 52 may alternatively constitute part of a quantum well structure, and peaks and troughs may be provided in the band structure through combination with another laminate.

### <Light-Emitting Layer>

The following further describes details of configurations of the light-emitting layer 50 in embodiments of the present disclosure.

### —Film Thickness—

Although no limitations are placed on the film thickness of the overall light-emitting layer 50, the film thickness thereof can be set as 1 μm to 8 μm, for example. Moreover, although no limitations are placed on the film thickness of each layer among the first layer 51 and the second layer 52 in the laminate of the light-emitting layer 50, the film thickness thereof can be set as approximately not less than 1 nm and not more than 15 nm, for example. The film thicknesses of these layers may be the same or different. Moreover, the film thicknesses of first layers 51 in the laminate may each be the same or different. The same applies to the film thicknesses of second layers 52. However, a case in which the film thicknesses of first layers 51 are the same and the film thicknesses of second layers 52 are the same and in which the light-emitting layer 50 has a superlattice structure is one preferred form in the present disclosure.

### —Number of Stacked Groups—

The following refers to FIG. 2. Although no limitations are placed on the number of groups of both a first layer 51 and a second layer 52, the number of groups can be set as not less than 3 groups and not more than 50 groups, for example. One extremity of the laminate can be a first layer 51 and the other extremity of the laminate can be a second layer 52. In this case, the number of groups of a first layer 51 and a second layer 52 is denoted as n groups (n is a natural number).

Moreover, one extremity of the laminate may be a first layer 51, a repeated structure of a second layer 52 and a first layer 51 may then be provided, and the other extremity of the laminate may be a first layer 51. Alternatively, both extremities may conversely be a second layer 52. In this case, the number of groups of a first layer 51 and a second layer 52 is denoted as n (n is a natural number), and the number of groups can be said to be n.5 groups. In FIG. 2, both extremities of the laminate are illustrated as being a first layer 51.

### —Composition Ratios—

So long as conditions relating to the composition wavelength difference and the lattice constant difference are satisfied, no limitations are placed on the composition ratios a, b, c, x, y, and z of the III-V compound semiconductor represented by a general formula (InₐGa_{b}Al_{c})(PₓAs_{y}Sb_{z}) in each layer among the first layer 51 and the second layer 52. However, the ranges from which these composition ratios are selected are preferably set such that ratios of lattice constant differences between a growth substrate and the first and second layers in the light-emitting layer are each 1% or less in order to inhibit deterioration of crystallinity of the light-emitting layer. In other words, it is preferable that a value obtained when an absolute value of the lattice constant difference between the growth substrate and the first layer is divided by an average value for the growth substrate and the first layer and a value obtained when an absolute value of the lattice constant difference between the growth substrate and the second layer is divided by an average value for the growth substrate and the second layer are each 1% or less. For example, when an InP substrate is used as a growth substrate in a case in which the central emission wavelength is not less than 1,000 nm and not more than 1,900 nm, the composition ratio a of In can be set as not less than 0.0 and not more than 1.0, the composition ratio b of Ga can be set as not less than 0.0 and not more than 1.0, the composition ratio c of Al can be set as not less than 0.0 and not more than 0.35, the composition ratio x of P can be set as not less than 0.0 and not more than 0.95, the composition ratio y of As can be set as not less than 0.15 and not more than 1.0, and the composition ratio z of Sb can be set as not less than 0.0 and not more than 0.7 in each layer. The composition ratios should be set from within these ranges as appropriate such that conditions relating to the composition wavelength difference and the ratio of lattice constant difference are satisfied. The central emission wavelength mentioned above is merely one example. For example, in the case of an InGaAsP semiconductor or an InGaAlAs semiconductor, the central emission wavelength can be set within a range of not less than 1,000 nm and not more than 2,200 nm, is preferably set as 1,300 nm or more, and is more preferably set as 1,400 nm or more. In a case in which Sb is included, the central emission wavelength can set as infrared of an even longer wavelength (11 μm or less).

### —Dopant—

Although no limitations are placed on a dopant in each layer of the light-emitting layer 50, it is preferable that the first layer 51 and the second layer 52 are each an i-type in order to reliably obtain the effects according to the present disclosure. However, each of the layers may be doped with an n-type or p-type dopant.

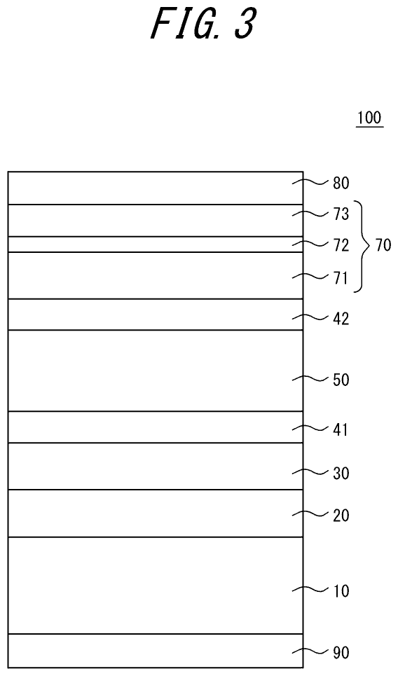

The following describes specific forms that the semiconductor light-emitting element according to the present disclosure can further include, but is not intended to limit the specific configuration of the semiconductor light-emitting element according to the present disclosure. A semiconductor light-emitting element 100 according to one embodiment of the present disclosure is described with reference to FIG. 3.

The semiconductor light-emitting element 100 according to one embodiment of the present disclosure includes at least the light-emitting layer 50 including the laminate set forth above, and preferably further includes desired configurations from among a supporting substrate 10, an intervening layer 20, a first conductivity type III-V compound semiconductor layer 30, a first spacer layer 41, a second spacer layer 42, and a second conductivity type III-V compound semiconductor layer 70, in this order. Moreover, the semiconductor light-emitting element 100 can further include a second conductivity type electrode 80 on the second conductivity type III-V compound semiconductor layer 70 and a first conductivity type electrode 90 at a rear surface of the supporting substrate 10. Note that when the first conductivity type is an n-type, the second conductivity type is a p-type. Conversely, when the first conductivity type is a p-type, the second conductivity type is an n-type. The following describes a form for a case in which the first conductivity type is an n-type and the second conductivity type is a p-type. In order to facilitate description, the first conductivity type III-V compound semiconductor layer 30 is denoted as an n-type semiconductor layer 30 and the second conductivity type III-V compound semiconductor layer 70 is denoted as a p-type semiconductor layer 70 in the following description, and the present embodiment is described in accordance with this specific example. As a result of the light-emitting layer 50 being sandwiched between the n-type semiconductor layer 30 and the p-type semiconductor layer 70, passing of current to the light-emitting layer 50 causes light emission through combination of electrons and holes in the light-emitting layer 50.

### <Growth Substrate>

A growth substrate should be selected as appropriate from compound semiconductor substrates such as an InP substrate, an InAs substrate, a GaAs substrate, a GaSb substrate, and an InSb substrate in accordance with the composition of the light-emitting layer 50. It is preferable that the conductivity type of each substrate is set to correspond to the conductivity type of a semiconductor layer on the growth substrate. Examples of compound semiconductor substrates that can be adopted in the present embodiment include an n-type InP substrate and an n-type GaAs substrate.

### <Supporting Substrate>

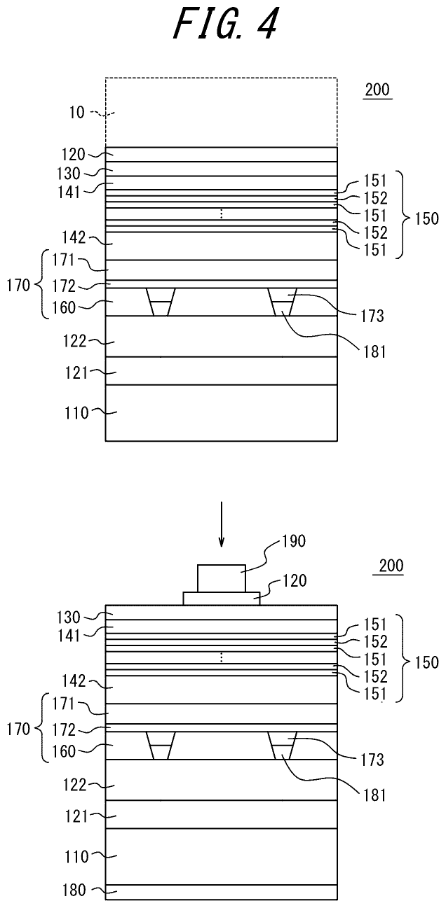

The supporting substrate 10 can be a growth substrate used to grow the light-emitting layer 50 on the supporting substrate 10. In a case in which a subsequently described bonding method is adopted, various types of substrates other than a growth substrate may be used as a supporting substrate 110 (refer to FIG. 4).

### <Intervening Layer>

An intervening layer 20 may be provided on the supporting substrate 10. In a case in which a growth substrate is used as the supporting substrate 10, the intervening layer 20 can be a III-V compound semiconductor layer. The intervening layer 20 can be used as an initial growth layer for epitaxial growth of a semiconductor layer on a supporting substrate 10 that serves as a growth substrate. Moreover, the intervening layer 20 can be used as a buffer layer for buffering lattice strain between a supporting substrate 10 that serves as a growth substrate and the n-type semiconductor layer 30, for example. Furthermore, the intervening layer 20 can also be used as an etching stop layer by performing lattice matching of the growth substrate and the intervening layer 20 while altering the semiconductor composition. For example, in a case in which the supporting substrate is an n-type InP substrate, the intervening layer 20 is preferably an n-type InGaAs layer. In this case, the composition ratio of In among the group III elements is preferably set as not less than 0.3 and not more than 0.7, and more preferably set as not less than 0.5 and not more than 0.6 in order to perform lattice matching of the intervening layer 20 with the InP growth substrate. Moreover, AlInAs, AlInGaAs, or InGaAsP may be adopted so long as composition ratios are set such that the lattice constant is close to that of the InP substrate to the same degree as with InGaAs described above. The intervening layer 20 may be a single layer or may be a composite layer (for example, a superlattice layer) with another layer.

<n-Type Semiconductor Layer>

An n-type semiconductor layer 30 can be provided on the supporting substrate 10 and, as necessary, the intervening layer 20, and this n-type semiconductor layer 30 can be used as an n-type cladding layer. The composition of a III-V compound semiconductor of the n-type semiconductor layer 30 should be set as appropriate in accordance with the composition of a III-V compound semiconductor of the light-emitting layer 50. For example, an n-type InP layer can be used in a case in which the light-emitting layer 50 is formed of an InGaAsP semiconductor or an InGaAlAs semiconductor. The n-type semiconductor layer 30 may have a single layer structure or may be a composite layer including a plurality of stacked layers. The thickness of the n-type cladding layer can, for example, be not less than 1 μm and not more than 5 μm.

### <Spacer Layers>

It is preferable that a first spacer layer 41 and a second spacer layer 42 are provided between the n-type semiconductor layer 30 and the light-emitting layer 50 and between the p-type semiconductor layer 70 and the light-emitting layer 50. The first spacer layer 41 can be an undoped or n-type III-V compound semiconductor layer, with the use of an i-type InP spacer layer, for example, being preferable. On the other hand, the second spacer layer 42 at the p-side is preferably an undoped III-V compound semiconductor layer. For example, an i-type InP spacer layer can be used. By providing an undoped spacer layer 42, it is possible to prevent unnecessary dopant diffusion between the light-emitting layer 50 and a p-type layer. The thicknesses of the spacers layers 41 and 42 are not limited and may, for example, be set as not less than 5 nm and not more than 500 nm.

<p-Type Semiconductor Layer>

A p-type semiconductor layer 70 can be provided on the light-emitting layer 50 and, as necessary, the second spacer layer 42. The p-type semiconductor layer 70 can include a p-type cladding layer 71 and a p-type contact layer 73 in order from the side where the light-emitting layer 50 is located. Provision of an intermediate layer 72 between the p-type cladding layer 71 and the p-type contact layer 73 is also preferable. The provision of the intermediate layer 72 makes it possible to ease lattice mismatch of the p-type cladding layer 71 and the p-type contact layer 73. The composition of a III-V compound semiconductor of the p-type semiconductor layer 70 should be set as appropriate in accordance with the composition of a III-V compound semiconductor of the light-emitting layer 50. For example, the p-type cladding layer may be p-type InP, the intermediate layer may be p-type InGaAsP, and the p-type contact layer 73 may be p-type InGaAs that does not contain P in a case in which the light-emitting layer 50 is formed of an InGaAlAs semiconductor. Although no specific limitations are placed on the film thickness of each layer in the p-type semiconductor layer 70, the film thickness of the p-type cladding layer 71 can be not less than 1 μm and not more than 5 μm, for example, the film thickness of the intermediate layer 72 can be not less than 10 nm and not more than 200 nm, for example, and the film thickness of the p-type contact layer 73 can be not less than 50 nm and not more than 200 nm, for example.

### <Electrodes>

A second conductivity type electrode 80 and a first conductivity type electrode 90 can be provided on the p-type semiconductor layer 70 and at a rear surface of the supporting substrate 10, respectively. A metal material used to form each of the electrodes can be a typically used material, examples of which include metals such as Ti, Pt, and Au, and also metals (Sn, etc.) that form a eutectic alloy with gold. Moreover, the electrode pattern of each of the electrodes can be any pattern without any limitations.

Although the preceding description describes an embodiment in which a compound semiconductor substrate is used as a growth substrate and in which this growth substrate is used as the supporting substrate 10, the present disclosure is not limited thereto. After each semiconductor layer has been formed on a growth substrate, a bonding method may be adopted to remove the growth substrate while affixing a semiconductor substrate such as a Si substrate, a metal substrate such as Mo, W, or Kovar, any of various types of submount substrate in which AlN, etc., is used, or the like, and this substrate may be used as the supporting substrate of the semiconductor light-emitting element according to the present disclosure (hereinafter, this method is referred to as a “bonding method”; refer to JP2018-006495A and JP2019-114650A). The following describes a case in which a bonding method is used with reference to FIG. 4. Note that the final two digits of reference signs in the drawings are the same as configurations that have already been described and repeated description thereof is omitted.

In a case in which a bonding method is used, each semiconductor layer is formed on a growth substrate 10, for example. After each semiconductor layer has been formed, a metal reflective layer 122 and a metal bonding layer 121 that is provided on a supporting substrate 110 are used to perform bonding, and then the growth substrate 10 is removed. An embodiment of the production method is described further below. The following provides a more specific description of the configuration of a semiconductor light-emitting element 200 after removal of the growth substrate 10. Besides each electrode, other layers that are not III-V compound semiconductors can also be provided in the semiconductor light-emitting element 200. For example, in a case in which a bonding method is used, formation can be performed such that a metal bonding layer 121 for supporting substrate bonding is included on a supporting substrate 110 formed of a Si substrate instead of the previously described initial growth layer, and then a p-type semiconductor layer 170, a light-emitting layer 150, and an n-type semiconductor layer 130 may be arranged sequentially thereon. Note that a metal reflective layer 122 can be provided on the metal bonding layer 121. Moreover, besides the III-V compound semiconductor layers, an ohmic electrode section 181 or a dielectric layer 160 surrounding ohmic electrode sections 181 present as island shapes can be provided on the metal reflective layer 122 as necessary. The dielectric material may be SiO₂, SiN, ITO, or the like.

As previously mentioned, although a case in which the first conductivity type semiconductor layer is an n-type and the second conductivity type semiconductor layer is a p-type is described as an example in the preceding embodiment, it should be understood that the n-type/p-type of the conductivity types of the layers can of course be reversed relative to that in the preceding embodiment.

### (Production Method of Semiconductor Light-Emitting Element)

A method of producing the above-described semiconductor light-emitting element according to the present disclosure includes at least a light-emitting layer formation step of forming a light-emitting layer 50, wherein the light-emitting layer formation step includes forming the above-described laminate through repetition of a first step of forming a first layer 51 and a second step of forming a second layer 52.

Steps of forming the various layers of the semiconductor light-emitting element 100 that were described with reference to FIG. 3 may also be included as necessary. Since III-V compound semiconductor materials that can be used as the first layer 51 and the second layer 52, conditions for the composition wavelength difference and lattice constant difference thereof, film thicknesses, the number of stacked groups, and so forth are as previously described, repeated description thereof is omitted.

Each III-V compound semiconductor layer can be formed by a commonly known thin film growth method such as metal organic chemical vapor deposition (MOCVD), molecular beam epitaxy (MBE), or sputtering. In the case of an InGaAsP semiconductor, trimethylindium (TMIn) as an In source, trimethylgallium (TMGa) as a Ga source, arsine (AsH₃) as an As source, and phosphine (PH₃) as a P source, for example, can be used in a specific mixing ratio, and these source gases can be used to perform vapor phase growth while also using a carrier gas to thereby enable epitaxial growth of an InGaAsP semiconductor layer of desired thickness in accordance with the growth time. Moreover, trimethylaluminum (TMA) or the like may be used as an Al source in a case in which Al is used as a group III element, and TMSb (trimethylantimony) or the like may be used as an Sb source in a case in which Sb is used as a group V element. Furthermore, in a case in which p-type or n-type doping of a semiconductor layer is performed, a dopant source gas containing Si, Zn, or the like in constituent elements may also be used as desired.

Formation of metal layers such as a first conductivity type electrode and a second conductivity type electrode can be performed by commonly known techniques such as sputtering, electron beam evaporation, and resistance heating, for example. When a dielectric layer is to be formed in a case in which a bonding method is adopted, a commonly known film formation method such as plasma CVD or sputtering may be used, and formation of irregularities can be performed by a commonly known etching method as necessary.

In a case in which the element illustrated in FIG. 4 is to be formed using a bonding method (refer to JP2018-006495A and JP2019-114650A mentioned above), the semiconductor light-emitting element can be produced as described below, for example.

First, various III-V compound semiconductor layers including an etching stop layer 120, an n-type semiconductor layer 130, a light-emitting layer 150, a p-type cladding layer 171, an intermediate layer 172, and a p-type contact layer 173 are formed sequentially on a growth substrate 10 (note that FIG. 4 illustrates a state after bonding and thus appears upside down). Next, p-type ohmic electrode sections 181 dispersed in island shapes are formed on the p-type contact layer 173. Thereafter, a resist mask is formed at the p-type ohmic electrode sections and at the peripheries thereof, and the p-type contact layer 173 is removed by wet etching or the like at locations other than locations where the ohmic electrode sections have been formed to expose the intermediate layer 172. A dielectric layer 160 is then formed on the intermediate layer 172. The dielectric layer 160 is partially etched so as to expose the tops of the p-type ohmic electrode sections 181 and the intermediate layer 172 in peripheral sections of the p-type ohmic electrode sections 181. A metal reflective layer 122 is formed over the entire surface inclusive of on the p-type ohmic electrode sections 181, the intermediate layer 172 exposed at peripheral sections of the p-type ohmic electrode sections 181, and the dielectric layer 160 in regions where it has not been removed.

On the other hand, a conductive Si substrate or the like is used as a supporting substrate 110, and a metal bonding layer 121 is formed on the supporting substrate. The metal reflective layer 122 and the metal bonding layer 121 are arranged in opposition and are bonded through hot compression or the like. The growth substrate is then removed by etching to expose the etching stop layer 120. A bonding-type semiconductor light-emitting element 200 can then be obtained by forming an n-type electrode 90 on the etching stop layer 120 and removing the etching stop layer 120 by etching with the exception of in an n-type electrode formation location; or by removing the etching stop layer 120 by etching with the exception of one section thereof and subsequently forming an n-type electrode 190 on the one section of the etching stop layer 120. As previously described, the n-type/p-type of conductivity types of the layers may be reversed relative to the example described above.

The following provides a more detailed description of the present disclosure using examples. However, the present disclosure is not in any way limited by the following examples.

### EXAMPLES

Semiconductor light-emitting elements according to Examples 1 to 4 and Comparative Examples 1 to 9, described below, were produced by a bonding method with 1,480 nm as a target central emission wavelength.

### Example 1

Configurations of III-V compound semiconductor layers of a semiconductor light-emitting element 200 according to Example 1 are described referring to reference signs in FIG. 4, and thicknesses and dopant concentrations thereof are shown in Table 2 for a state after growth on a growth substrate, prior to bonding to a supporting substrate described further below. A S-doped n-type InP substrate was used as a growth substrate 10. On a (100) face of the n-type InP substrate (S-doped; dopant concentration: 2.0×10¹⁸ atoms/cm³), an n-type InP layer of 100 nm in thickness and an n-type In_{0.57}Ga_{0.43}As layer of 20 nm in thickness (respectively an initial growth layer and an etching stop layer 120), an n-type InP layer of 3,500 nm in thickness (n-type semiconductor layer 130 serving as an n-type cladding layer), an i-type InP layer of 100 nm in thickness (first spacer layer 141), a light-emitting layer 150 described in detail further below, an i-type InP layer of 320 nm in thickness (second spacer layer 142), a p-type InP layer of 2,400 nm in thickness (p-type cladding layer 171), a p-type In_{0.8}Ga_{0.2}As_{0.5}P_{0.5} layer of 50 nm in thickness (intermediate layer 172), and a p-type In_{0.57}Ga_{0.43}As layer of 100 nm in thickness (p-type contact layer 173) were formed sequentially by MOCVD. The n-type InP layer and n-type InGaAs layer (respectively an initial growth layer and an etching stop layer 120) and the n-type InP layer (n-type semiconductor layer 130 serving as an n-type cladding layer) were subjected to Si doping such as to have a dopant concentration of 5.0×10¹⁷ atoms/cm³. The p-type InP layer (p-type cladding layer 171) was subjected to Zn doping such as to have a dopant concentration of 7.0×10¹⁷ atoms/cm³. The p-type InGaAsP layer (intermediate layer 172) and the p-type InGaAs layer (p-type contact layer 173) were subjected to Zn doping such as to have a dopant concentration of 1.5×10¹⁹ atoms/cm³.

In formation of the light-emitting layer 150, an i-type Inₐ₁Ga_{b1}Al_{c1}As layer (first layer 151) serving as a barrier layer was first formed, and then 10 i-type Inₐ₂Ga_{b2}Al_{c2}As layers (second layers 152) serving as well layers and 10 i-type Inₐ₁Ga_{b1}Al_{c1}As layers (first layers 151) serving as barrier layers were stacked alternately so as to obtain a 10.5 group laminate. In other words, both extremities of the light-emitting layer 150 are barrier layers (first layers 151). The barrier layers (first layers 151) are each In_{0.5264}Ga_{0.3597}Al_{0.1139}As of 8 nm in thickness. In other words, the In composition ratio (a1) is 0.5264, the Ga composition ratio (b1) is 0.3597, and the Al composition ratio (c1) is 0.1139. Moreover, the well layers (second layers 152) are each In_{0.5663}Ga_{0.3516}Al_{0.0821}As of 10 nm in thickness. In other words, the In composition ratio (a2) is 0.5663, the Ga composition ratio (b2) is 0.3516, and the Al composition ratio (c2) is 0.0821. In addition, lattice constants were calculated as previously described, and the band structure was calculated using simulation software (SiLENSe) produced by STR Japan K.K. Values for the thicknesses, composition ratios, composition wavelengths, and lattice constants of the barrier layers (first layers 151) and the well layers (second layers 152) are recorded in Table 3. The composition wavelength difference for composition ratios in the light-emitting layer of Example 1 was 126.6 nm, a value obtained when an absolute value of the difference between the two lattice constants was divided by an average value of the two lattice constants (ratio of lattice constant difference) was a percentage of 0.28%, and a ratio Dc/(Dc+Dv) of the well depth (Dc) at the conduction band-side relative to the total of the well depth (Dc) at the conduction band-side and the well depth (Dv) at the valence band-side was a percentage of 66.5%. These values are recorded in Table 4. The total film thickness of the light-emitting layer is 180 nm. Note that the compositions of the layers in Example 1 described above are values that were measured through SIMS analysis. Moreover, for each layer in the light-emitting layer, a solid phase ratio of that layer was confirmed by SIMS analysis after the light-emitting layer had been exposed.

TABLE 2

| | | | | Dopant | | |
|---|---|---|---|---|---|---|
| | | | Thickness | concentration | | |
| Semiconductor layer | | Composition | nm | cm⁻³ | | |
| p-Type contact layer | | p-InGaAs | 100 | 1.5 × 10¹⁹ | | |
| Intermediate layer | | p-InGaAsP | 50 | 5.0 × 10¹⁸ | | |
| p-Type cladding layer | | p-InP | 2400 | 7.0 × 10¹⁷ | | |
| Second spacer layer | | i-InP | 320 | — | | |
| Light-emitting layer | Barrier layer | i-InGaAlAs | 8 | — | | |
| (MQW active layer) | Well layer | i-InGaAlAs | 10 | — | | |
| | Barrier layer | i-InGaAlAs | 8 | — | | |
| | Well layer | i-InGaAlAs | 10 | — | | |
| | | . | | | {close oversize brace} | (Barrier layer + well layer) × 10 groups |
| | | . | | | | |
| | | . | | | | |
| | Barrier layer | i-InGaAlAs | 8 | — | | |
| | Well layer | i-InGaAlAs | 10 | — | | |
| | Barrier layer | i-InGaAlAs | 8 | — | | |

| | | | |
|---|---|---|---|
| First spacer layer | i-InP | 100 | — |
| n-Type cladding layer | n-InP | 3500 | 5.0 × 10¹⁷ |
| Etching stop layer | n-InGaAs | 20 | 5.0 × 10¹⁷ |
| Initial growth layer | n-InP | 100 | 5.0 × 10¹⁷ |
| Growth substrate | n-InP | — | 2.0 × 10¹⁸ |

p-Type ohmic electrode sections 181 (Au/AuZn/Au; total thickness: 530 nm) were formed in dispersed island shapes on the p-type contact layer. Note that in island pattern formation, a resist pattern was formed, an ohmic electrode 181 was then vapor deposited, and lift-off of the resist pattern was performed to form the island pattern. The proportion constituted by area of the p-type ohmic electrode sections relative to chip area (contact area ratio) is 0.95% and the chip size is 280 μm-square.

Next, a resist mask was formed at the p-type ohmic electrode sections 181 and the peripheries thereof, and the p-type contact layer 173 was removed through tartaric acid-hydrogen peroxide wet etching at locations other than the locations where the ohmic electrode sections 181 had been formed to expose the intermediate layer 172. Thereafter, a dielectric layer 160 (thickness: 700 nm) formed of SiO₂ was formed over the entirety of the intermediate layer 172 by plasma CVD. A window pattern having a shape provided with a width of 3 μm in a width direction and a longitudinal direction in a region above each of the p-type ohmic electrode sections 181 was formed by a resist, and the dielectric layer 160 was removed by wet etching using BHF at the p-type ohmic electrode sections 181 and the peripheries thereof to expose the tops of the p-type ohmic electrode sections 181 and the intermediate layer 172 at the peripheries of the p-type ohmic electrode sections (not illustrated).

Next, a metal reflective layer 122 was formed over the entirety of the intermediate layer 172 (tops of p-type ohmic electrode sections 181, top of dielectric layer 60, and intermediate layer 172 exposed at peripheries of p-type ohmic electrode sections) by vapor deposition. The thicknesses of metal layers in the metal reflective layer (Ti/Au/Pt/Au) are, in order, 2 nm, 650 nm, 100 nm, and 900 nm. On the other hand, a metal bonding layer 121 was formed on a conductive Si substrate (thickness: 200 μm) serving as a supporting substrate. The thicknesses of metal layers in the metal bonding layer (Ti/Pt/Au) are, in order, 650 nm, 10 nm, and 900 nm.

The metal reflective layer 122 and the metal bonding layer 121 were arranged in opposition and were hot compression bonded at 315° C. The n-type InP substrate 10 was then removed by wet etching using dilute hydrochloric acid.

An n-type electrode 190 (Au (thickness: 10 nm)/Ge (thickness: 33 nm)/Au (thickness: 57 nm)/Ni (thickness: 34 nm)/Au (thickness: 800 nm)/Ti (thickness: 100 nm)/Au (thickness: 1,000 nm)) was then formed as a wiring section of an upper surface electrode on the n-type etching stop layer 120 through resist pattern formation, n-type electrode vapor deposition, and resist pattern lift-off. A pad section (Ti (thickness: 150 nm)/Pt (thickness: 100 nm)/Au (thickness: 2,500 nm)) was then further formed on the n-type electrode to form an upper surface electrode pattern. The n-type etching stop layer 120 was then removed by wet etching with the exception of that directly below the n-type electrode 190 and in proximity thereto, and surface roughening treatment was performed. Thereafter, a dielectric protective film (not illustrated) was formed over the upper surface and the side surface of the light-emitting element 100 with the exception of an upper surface of the pad section.

### Example 2

A semiconductor light-emitting element according to Example 2 was obtained in the same way as in Example 1 with the exception that the composition of the first layers 151 serving as barrier layers was changed from In_{0.5264}Ga_{0.3597}Al_{0.1139}As to In_{0.5264}Ga_{0.3166}Al_{0.1570}As. Values for the thicknesses, composition ratios, composition wavelengths, and lattice constants of the barrier layers (first layers 151) and the well layers (second layers 152) are recorded in Table 3. The composition wavelength difference for composition ratios in the light-emitting layer of Example 2 was 218.4 nm, a value obtained when an absolute value of the difference between the two lattice constants was divided by an average value of the two lattice constants (ratio of lattice constant difference) was 0.28%, and a ratio Dc/(Dc+Dv) of the well depth (Dc) at the conduction band-side relative to the total of the well depth (Dc) at the conduction band-side and the well depth (Dv) at the valence band-side was 68.7%. These values are recorded in Table 4.

### Examples 3 to 5 and Comparative Examples 1 to 9

Semiconductor light-emitting elements according to Examples 3 to 5 and Comparative Examples 1 to 9 were obtained in the same way as in Example 1 with the exception that the composition of the barrier layers (first layers 151) and the composition and thickness of the well layers (second layers 152) were changed as indicated in Table 3.

The composition wavelengths and lattice constants calculated from the composition of the barrier layers (first layers 151) and the composition of the well layers (second layers 152) for each example and comparative example are also recorded in Table 3. Furthermore, the composition wavelength difference of the barrier layers (first layers 151) and the well layers (second layers 152), a value obtained when an absolute value of the difference between the two lattice constants thereof was divided by an average value of the lattice constants (ratio of lattice constant difference), calculated values of the conduction band well depth (Dc) and the valence band well depth (Dv), and a value of a ratio Dc/(Dc+Dv) relative to the total of the well depth (Dc) at the conduction band-side and the well depth (Dv) at the valence band-side are recorded in Table 4.

TABLE 3

| | Barrier layer | | | | | | | | |
|---|---|---|---|---|---|---|---|---|---|
| | | Group III | | | Group V | | | | |
| | | In | Ga | Al | As | P | | | Well layer |
| | Thick- | compo- | compo- | compo- | compo- | compo- | Composition | Lattice | Thick- |
| | ness | sition | sition | sition | sition | sition | wavelength | constant | ness |
| | [nm] | ratio | ratio | ratio | ratio | ratio | [nm] | [nm] | [nm] |
| Comparative | 8 | 0.5264 | 0.3982 | 0.0754 | 1.0000 | — | 1501.2 | 0.5866 | 10 |
| Example 1 | | | | | | | | | |
| Comparative | 8 | 0.5321 | 0.3816 | 0.0863 | 1.0000 | — | 1459.2 | 0.5869 | 10 |
| Example 2 | | | | | | | | | |
| Example 1 | 8 | 0.5264 | 0.3597 | 0.1139 | 1.0000 | — | 1409.8 | 0.5866 | 10 |
| Example 2 | 8 | 0.5264 | 0.3166 | 0.1570 | 1.0000 | — | 1318.0 | 0.5866 | 10 |
| Example 3 | 8 | 0.5264 | 0.2665 | 0.2071 | 1.0000 | — | 1223.4 | 0.5866 | 10 |
| Example 4 | 8 | 0.5264 | 0.1626 | 0.3110 | 1.0000 | — | 1060.0 | 0.5866 | 10 |
| Example 5 | 8 | 0.5264 | 0.3166 | 0.1570 | 1.0000 | — | 1318.0 | 0.5866 | 10 |
| Comparative | 8 | 0.5961 | 0.4039 | — | 0.8547 | 0.1453 | 1580.5 | 0.5865 | 10 |
| Example 3 | | | | | | | | | |
| Comparative | 8 | 0.6340 | 0.3660 | — | 0.7630 | 0.2370 | 1495.5 | 0.5860 | 10 |
| Example 4 | | | | | | | | | |
| Comparative | 8 | 1.0000 | — | — | — | 1.0000 | 918.3 | 0.5869 | 10 |
| Example 5 | | | | | | | | | |
| Comparative | 8 | 0.7302 | 0.2698 | — | 0.5725 | 0.4275 | 1332.9 | 0.5865 | 5 |
| Example 6 | | | | | | | | | |
| Comparative | 8 | 0.7156 | 0.2844 | — | 0.5851 | 0.4149 | 1341.4 | 0.5858 | 5 |
| Example 7 | | | | | | | | | |
| Comparative | 8 | 0.7208 | 0.2792 | — | 0.5886 | 0.4114 | 1345.9 | 0.5862 | 5 |
| Example 8 | | | | | | | | | |
| Comparative | 8 | 0.7085 | 0.2915 | — | 0.6102 | 0.3898 | 1363.7 | 0.5863 | 5 |
| Example 9 | | | | | | | | | |

| | Well layer | | | | | | |
|---|---|---|---|---|---|---|---|
| | Group III | | | Group V | | | |
| | In | Ga | Al | As | P | | |
| | compo- | compo- | compo- | compo- | compo- | Composition | Lattice |
| | sition | sition | sition | sition | sition | wavelength | constant |
| | ratio | ratio | ratio | ratio | ratio | [nm] | [nm] |
| Comparative | 0.5663 | 0.3515 | 0.0822 | 1.0000 | — | 1536.4 | 0.5883 |
| Example 1 | | | | | | | |
| Comparative | 0.5435 | 0.3811 | 0.0754 | 1.0000 | — | 1522.7 | 0.5873 |
| Example 2 | | | | | | | |
| Example 1 | 0.5663 | 0.3516 | 0.0821 | 1.0000 | — | 1536.4 | 0.5883 |
| Example 2 | 0.5663 | 0.3516 | 0.0821 | 1.0000 | — | 1536.4 | 0.5883 |
| Example 3 | 0.5435 | 0.3976 | 0.0589 | 1.0000 | — | 1565.0 | 0.5873 |
| Example 4 | 0.5435 | 0.3976 | 0.0589 | 1.0000 | — | 1565.0 | 0.5873 |
| Example 5 | 0.5778 | 0.3378 | 0.0844 | 1.0000 | — | 1556.3 | 0.5887 |
| Comparative | 0.6196 | 0.3804 | — | 0.8588 | 0.1412 | 1618.1 | 0.5885 |
| Example 3 | | | | | | | |
| Comparative | 0.6460 | 0.3540 | — | 0.8810 | 0.1190 | 1701.0 | 0.5916 |
| Example 4 | | | | | | | |
| Comparative | 0.5950 | 0.4050 | — | 0.9105 | 0.0895 | 1667.9 | 0.5886 |
| Example 5 | | | | | | | |
| Comparative | 0.5451 | 0.4549 | — | 0.9272 | 0.0728 | 1637.0 | 0.5852 |
| Example 6 | | | | | | | |
| Comparative | 0.5589 | 0.4411 | — | 0.9222 | 0.0778 | 1639.1 | 0.5861 |
| Example 7 | | | | | | | |
| Comparative | 0.5270 | 0.4730 | — | 0.9306 | 0.0694 | 1630.6 | 0.5838 |
| Example 8 | | | | | | | |
| Comparative | 0.5412 | 0.4588 | — | 0.9303 | 0.0697 | 1638.5 | 0.5850 |
| Example 9 | | | | | | | |

TABLE 4

| | | Ratio of | | | | Central | | | | | |
|---|---|---|---|---|---|---|---|---|---|---|---|
| | Composition | lattice | Conduction | Valence | | emission | | | | | Forward |
| | wavelength | constant | band well | band well | | wave- | Full width at half | | Light emission | | voltage |
| | difference | difference | depth | depth | Dc/(Dc + | length λp | maximum FWHM | | output Po | | Vf |
| | [nm] | [%] | Dc [eV] | Dv [eV] | Dv) | [nm] | [nm] | Evaluation | [mW] | Evaluation | [V] |
| Comparative | 35.2 | 0.28% | 0.010 | 0.009 | 54.2% | 1480.1 | 123.2 | − | 4.46 | + | 1.06 |
| Example 1 | | | | | | | | | | | |
| Comparative | 63.4 | 0.08% | 0.024 | 0.012 | 67.4% | 1485.1 | 125.0 | − | 4.42 | + | 1.06 |
| Example 2 | | | | | | | | | | | |
| Example 1 | 126.6 | 0.28% | 0.048 | 0.024 | 66.5% | 1475.2 | 119.4 | + | 4.82 | ++ | 1.08 |
| Example 2 | 218.4 | 0.28% | 0.092 | 0.042 | 68.7% | 1466.8 | 106.4 | ++ | 4.86 | ++ | 1.08 |
| Example 3 | 341.6 | 0.12% | 0.157 | 0.064 | 71.1% | 1492.9 | 107.5 | ++ | 4.49 | + | 1.07 |
| Example 4 | 504.9 | 0.12% | 0.272 | 0.106 | 72.0% | 1486.6 | 105.6 | ++ | 4.51 | + | 1.07 |
| Example 5 | 238.3 | 0.36% | 0.094 | 0.045 | 67.8% | 1467.4 | 104.2 | ++ | 4.94 | ++ | 1.08 |
| Comparative | 37.5 | 0.35% | 0.011 | 0.008 | 57.9% | 1491.1 | 117.4 | + | 4.54 | + | 1.06 |
| Example 3 | | | | | | | | | | | |
| Comparative | 205.4 | 0.96% | 0.045 | 0.055 | 45.2% | 1476.7 | 128.8 | − | 3.97 | − | 1.02 |
| Example 4 | | | | | | | | | | | |
| Comparative | 749.6 | 0.28% | 0.358 | 0.249 | 59.0% | 1480.2 | 125.0 | − | 3.00 | − | 1.08 |
| Example 5 | | | | | | | | | | | |
| Comparative | 304.1 | 0.23% | 0.065 | 0.108 | 37.5% | 1468.8 | 126.8 | − | 3.25 | − | 1.07 |
| Example 6 | | | | | | | | | | | |
| Comparative | 297.7 | 0.05% | 0.068 | 0.100 | 40.5% | 1470.2 | 123.7 | − | 3.53 | − | 1.08 |
| Example 7 | | | | | | | | | | | |
| Comparative | 284.7 | 0.40% | 0.054 | 0.107 | 33.3% | 1467.9 | 121.8 | − | 3.26 | − | 1.08 |
| Example 8 | | | | | | | | | | | |
| Comparative | 274.8 | 0.22% | 0.054 | 0.098 | 35.5% | 1430.9 | 123.0 | − | 3.90 | − | 1.09 |
| Example 9 | | | | | | | | | | | |

For each of the semiconductor light-emitting elements according to Examples 1 to 5 and Comparative Examples 1 to 9, the forward voltage Vf (V), the light emission output Po (mW) according to an integrating sphere, and the central emission wavelength λp (nm) and full width at half maximum (FWHM; units: nm) according to a spectral analyzer (AQ6374 produced by Yokogawa Test & Measurement Corporation) were measured for when a 36 mA current was passed using a constant current/voltage power supply. Note that in each case, an average value of measurement results for three samples was determined. The measurement results are shown in Table 4. Evaluations of the full width at half maximum and the light emission output are also shown together therewith.

In Table 4, the full width at half maximum (FWHM) of a light emission peak and the light emission output are evaluated by the following standards.

### Full Width at Half Maximum

++ . . . Less than 110 nm
+ . . . Not less than 110 nm and less than 120 nm
− . . . 120 nm or more

### Light Emission Output

++ . . . 4.80 mW or more
+ . . . Not less than 4.40 mW and less than 4.80 mW
− . . . Less than 4.40 mW

It can be seen from the results in Table 4 that the examples having both a composition wavelength difference and a Dc/(Dc+Dv) value in accordance with the present disclosure each have high light emission output and a small full width at half maximum. Upon comparison of Comparative Examples 1 and 2 and Examples 1 to 5 in which one type of group V element is used, the examples have higher light emission output and a smaller value for full width at half maximum. Moreover, it can be seen that relative to Comparative Examples 1 and 3 in which the composition wavelength difference is 50 nm or less, Examples 1, 2, and 5 have significantly improved light emission output, whereas Examples 3 and 4 have a similar level of light emission output while also having a smaller full width at half maximum. Comparative Examples 4 to 9 have low output compared to the examples because despite having a large composition wavelength difference, Comparative Examples 4 to 9 have a Dc/(Dc+Dv) value of less than 65%.

### INDUSTRIAL APPLICABILITY

The present disclosure is useful in terms of enabling the provision of a semiconductor light-emitting element having good light emission characteristics compared to conventional light-emitting elements and a method of producing the same.

### REFERENCE SIGNS LIST

10 supporting substrate
20 intervening layer
30 n-type semiconductor layer
41 first spacer layer
42 second spacer layer
50 light-emitting layer
51 first layer
52 second layer
60 dielectric layer
70 p-type semiconductor layer
71 p-type cladding layer
72 intermediate layer
73 p-type contact layer
80 second conductivity type electrode
90 first conductivity type electrode
100 semiconductor light-emitting element

1. A semiconductor light-emitting element comprising a light-emitting layer including a laminate in which a first III-V compound semiconductor layer and a second III-V compound semiconductor layer are stacked repeatedly, wherein
group III element in the first III-V compound semiconductor layer and the second III-V compound semiconductor layer is one type or two or more types selected from the group consisting of Al, Ga, and In,
group V element in the first III-V compound semiconductor layer and the second III-V compound semiconductor layer is one type or two or more types selected from the group consisting of As, Sb, and P,
a composition wavelength difference between a composition wavelength of the first III-V compound semiconductor layer and a composition wavelength of the second III-V compound semiconductor layer is 70 nm or more,
in a band structure of the laminate, well depth (Dc) at a conduction band-side is larger than well depth (Dv) at a valence band-side, and a ratio Dc/(Dc+Dv) of the well depth (Dc) at the conduction band-side created due to the composition wavelength difference relative to a total of the well depth (Dc) at the conduction band-side and the well depth (Dv) at the valence band-side is 65% or more, and
a value obtained when an absolute value of a lattice constant difference between a lattice constant of the first III-V compound semiconductor layer and a lattice constant of the second III-V compound semiconductor layer is divided by an average value of the lattice constant of the first III-V compound semiconductor layer and the lattice constant of the second III-V compound semiconductor layer is not less than 0.10% and not more than 0.40%.

2. (canceled)

3. The semiconductor light-emitting element according to claim 1, wherein the well depth (Dv) at the valence band-side is 0.11 eV or less.

4. The semiconductor light-emitting element according to claim 1, wherein the group V element in the first III-V compound semiconductor layer and the second III-V compound semiconductor layer is one type selected from the group consisting of As, Sb, and P.

5. The semiconductor light-emitting element according to claim 1, wherein the composition wavelength difference between the composition wavelength of the first III-V compound semiconductor layer and the composition wavelength of the second III-V compound semiconductor layer is not less than 100 nm and not more than 290 nm.

6. A method of producing the semiconductor light-emitting element according to claim 1, comprising a light-emitting layer formation step of forming the light-emitting layer, wherein
the light-emitting layer formation step includes forming the laminate through repetition of a first step of forming the first III-V compound semiconductor layer and a second step of forming the second III-V compound semiconductor layer.
